(19) United States
(12) Patent Application Publication
(10) Pub. No.: US 2017/0159181 A1
(43) Pub. Date: Jun. 8, 2017

(54) SUBSTRATE PROCESSING APPARATUS

(71) Applicant: HITACHI KOKUSAI ELECTRIC INC., Tokyo (JP)

(72) Inventors: Kazuyuki TOYODA, Toyama-shi (JP); Tetsuo YAMAMOTO, Toyama-shi (JP)

(73) Assignee: HITACHI KOKUSAI ELECTRIC INC., Tokyo (JP)

(21) Appl. No.: 15/366,697

(22) Filed: Dec. 1, 2016

(30) Foreign Application Priority Data
Dec. 2, 2015 (JP) 2015-235692

(51) Int. Cl. C23C 16/46; C23C 16/52; C23C 16/458; C23C 16/44; C23C 16/455

(52) U.S. Cl. CPC C23C 16/46; C23C 16/4412; C23C 16/45582; C23C 16/4586; C23C 16/52

(57) ABSTRACT

A substrate processing apparatus includes a substrate support part provided with a first heating part, configured to heat a substrate, a gas supply part installed above the substrate support part and configured to supply a process gas to the substrate, a first exhaust port configured to exhaust an atmosphere of a process space existing above the substrate support part, a gas distribution part installed to face the substrate support part, a lid part provided with a second exhaust port configured to exhaust a buffer space existing between the gas supply part, and the gas distribution part, a rectifying part installed within the buffer space and provided with a second heating part at least partially facing the second exhaust port, the rectifying part configured to rectify the process gas, and a control part configured to control the second heating part.

### CROSS-REFERENCE TO RELATED APPLICATION

This application is based upon and claims the benefit of priority from Japanese Patent Application No. 2015 -235692, filed on Dec. 2, 2015 the entire contents of which are incorporated herein by reference.

### TECHNICAL FIELD

The present disclosure relates to a substrate processing apparatus.

### BACKGROUND

As one process for manufacturing a semiconductor device, there has been performed a process of supplying a process gas and a reaction gas to a substrate to form a film on the substrate.

However, there may be a case where the temperature distribution in a substrate becomes uneven which results in deteriorating processing uniformity.

### SUMMARY

The present disclosure provides some embodiments of a technique capable of improving the processing uniformity of a substrate.

According to one embodiment of the present disclosure, there is provided a substrate processing apparatus, including: a substrate support part provided with a first heating part configured to heat a substrate; a gas supply part installed above the substrate support part and configured to supply a process gas to the substrate; a first exhaust port configured to exhaust an atmosphere of a process space existing above the substrate support part; a gas distribution part installed to face the substrate support part; a lid part provided with a second exhaust port configured to exhaust a buffer space existing between the gas supply part and the gas distribution part; a rectifying part installed within the buffer space and provided with a second heating part at least partially facing the second exhaust port, the rectifying part configured to rectify the process gas; and a control part configured to control the second heating part.

### BRIEF DESCRIPTION OF THE DRAWINGS

FIG. 1 is a schematic configuration view of a substrate processing apparatus according to one embodiment.

FIG. 2 is a schematic configuration view of a second heating part according to one embodiment.

FIG. 3 is a view illustrating a connection relationship between a temperature measurement part and a power supply control part of a second heating part according to one embodiment.

FIG. 4 is a schematic configuration view of a gas supply system of a substrate processing apparatus suitably used in one embodiment.

FIG. 5 is a schematic configuration view of a controller of a substrate processing apparatus suitably used in one embodiment.

FIG. 6 is a diagram illustrating a first table suitably used in one embodiment.

FIG. 7 is a diagram illustrating a second table suitably used in one embodiment.

FIG. 8 is a diagram illustrating a third table suitably used in one embodiment.

FIG. 9 is a flowchart illustrating a substrate processing process according to one embodiment.

FIG. 10 is a diagram illustrating a sequence of gas supply to a shower head according to one embodiment.

### DETAILED DESCRIPTION

A first embodiment of the present disclosure will now be described in detail with reference to the drawings.

### (1) Configuration of Substrate Processing Apparatus

First, a substrate processing apparatus according to a first embodiment will be described.

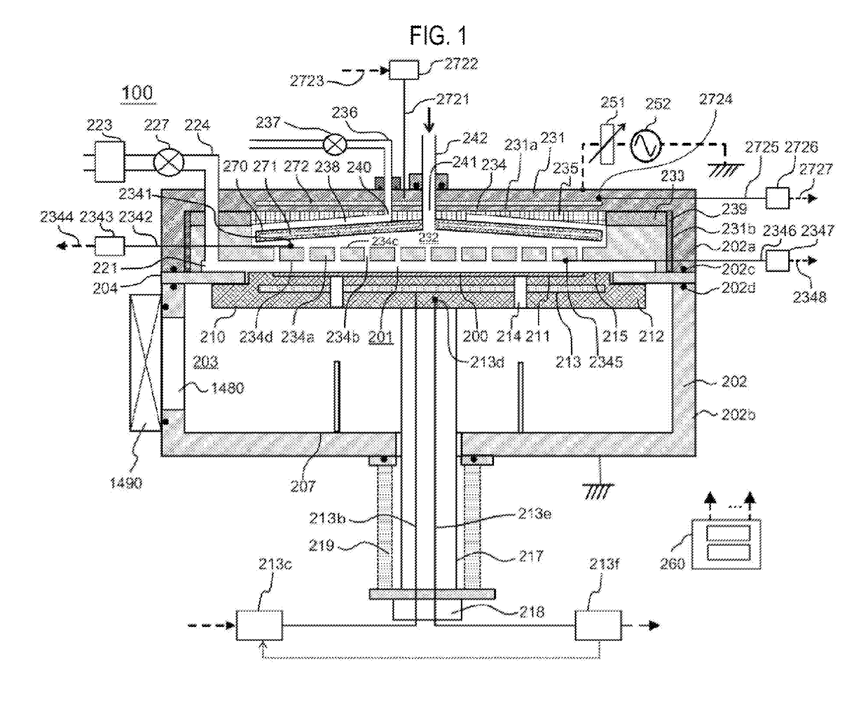

A substrate processing apparatus 100 according to the present embodiment will be described. The substrate processing apparatus 100 is a thin film forming unit. As illustrated in FIG. 1, the substrate processing apparatus 100 is configured as a single-substrate-type substrate processing apparatus. In the substrate processing apparatus 100, one process of manufacturing a semiconductor device is performed. The term “semiconductor device” used herein refers to one or more of an integrated circuit and an electronic element group (a resistance element, a coil element, a capacitor element or a film serving as a semiconductor element). A process of forming a dummy film or the like, which may be needed in the course of manufacturing a semiconductor device, is performed.

The present inventors have found that, when the process temperature becomes a high temperature in the substrate processing apparatus 100, one or more of the following problems arise. The term “high temperature” used herein refers to a temperature of, for example, 400degrees C. to 850 degrees C.

### <Problem 1>

When the processing temperature becomes a high temperature, the heat generated from a heater 213 is radiated toward an upper container 202a. Thus, a problem arises in that the temperature uniformity of a wafer 200 is lowered to degrade the processing uniformity. In this regard, the radiation of heat is generated by the movement of heat such as heat conductivity, heat transfer or the like. Furthermore, the radiation of heat is generated in, for example, the outer periphery of a gas distribution plate 234a as a gas distribution part, the outer periphery or the upper side of a rectifying part 270, or an exhaust port 240 as a second exhaust part. Heat is moved to the outside of the substrate processing apparatus 100 or the region having a lower temperature than a process chamber 201.

### <Problem 2>

Since it is necessary to control a heater 213 in order to compensate for the radiation of heat, the power consumption increases.

### <Problem 3>

Since a temperature difference is generated between a substrate and a lid 231 of an upper container 202a, a thermal stress is applied to a distribution plate 234a installed therebetween. There is a possibility that the distribution plate 234a is deformed or damaged by the thermal stress. Furthermore, a film adhering to the distribution plate 234a is peeled off by the thermal stress, thereby generating particles.

### <Problem 4>

Since a temperature difference is generated between the upper and lower ends of a rectifying part 270 or between the center and periphery of the rectifying part 270, a thermal stress is generated. Thus, a film adhering to the surface of the rectifying part 270 is peeled off by the thermal stress, thereby generating particles.

### <Problem 5>

A temperature difference is generated between the upper and lower ends of an exhaust guide 235 or between the center and periphery of the exhaust guide 235, which causes a thermal stress to be applied. Thus, a film adhering to the rear surface of the rectifying part 270 or an exhaust flow path 238 is peeled off by the thermal stress, thereby generating particles.

The present inventors have found a substrate processing apparatus described below, as a technique for resolving these problems.

As illustrated in FIG. 1, a substrate processing apparatus 100 includes a process container 202. The process container 202 is configured as, for example, a flat closed container having a circular horizontal cross section. Furthermore, the process container 202 is made of a metallic material such as aluminum (Al), stainless steel (SUS) or the like, or quartz. A process space (process chamber) 201 for processing a wafer 200 such as a silicon wafer or the likes as a substrate and a transfer space 203 are formed within the process container 202. The process container 202 includes an upper container 202a and a lower container 202b. A partition plate 204 is installed between the upper container 202a and the lower container 202b. A space surrounded by the upper container 202a and positioned above the partition plate 204 is called the process space (process chamber) 201. A space surrounded by the lower container 202b and positioned under the partition plate 204 is called the transfer space 203.

A substrate loading/unloading gate 1480 adjoining a gate valve 205 is installed on the side surface of the lower container 202b. The wafer 200 is moved toward or away from a transfer chamber (not shown) through the substrate loading/unloading gate 1480. A plurality of lift pins 207 is installed in the bottom portion of the lower container 202b. The lower container 202b is grounded.

A substrate support part 210 configured to support the wafer 200 is installed within the process chamber 201. The substrate support part 210 includes a substrate mounting surface 211 on which the wafer 200 is mounted and a substrate mounting table 212 provided on its front surface with the substrate mounting surface 211 and an outer peripheral surface 215. Preferably, a heater 213 as a first heating part is installed. By installing the first heating part, it is possible to heat the substrate and to improve the quality of a film formed on the substrate. In the substrate mounting table 212, through-holes 214 through which the lift pins 207 pass may be respectively installed in the positions corresponding to the lift pins 207. The height of the substrate mounting surface 211 formed on the front surface of the substrate mounting table 212 may be set lower than the height of the outer peripheral surface 215 by length corresponding to the thickness of the wafer 200. With this configuration, the difference between the height of the upper surface of the wafer 200 and the height of the outer peripheral surface 215 of the substrate mounting table 212 becomes small. It is therefore possible to suppress a turbulent gas flow which may otherwise be generated by the difference in height. Also, in the case where the turbulent gas flow does not affect the processing uniformity of the wafer 200, the outer peripheral surface 215 may be set to be flush with or higher than the substrate mounting surface 211.

A power supply line 213b is connected to the heater 213 as the first heating part. A power control part 213c for controlling the temperature of the heater 213 is connected to the opposite end of the power supply line 213b from the heater 213. A temperature detection part 213d configured to measure the temperature of the heater 213 is installed in the vicinity of the heater 213. The temperature detection part 213d is connected to a first temperature measurement part 213f via a wire 213e.

The power control part 213c as a temperature control part is electrically connected to a controller 260. The controller 260 transmits an electric power value for controlling the heater 213 to the power control part 213c. The power control part 213c, which has received the electric power value, supplies the electric power corresponding to the information to the heater 213, thereby controlling the temperature of the heater 213.

The first temperature measurement part 213f measures the temperature of the heater 213 through the temperature detection part 213d and the wire 213e. The detected temperature is measured as a voltage value. Even in other temperature measurement parts described later, the temperature is similarly measured as a voltage value. The temperature (voltage value) measured by the first temperature measurement part 213f is analog-to-digital converted in the first temperature measurement part 213f, thereby generating temperature data (temperature information). The first temperature measurement part 213f is electrically connected to the controller 260 and is configured to transmit the generated temperature information to the controller 260. Furthermore, the first temperature measurement part 213f may be configured to transmit the temperature information to the power control part 213c. The power control part 213c may be configured to feedback-control the temperature of the heater 213 based on the temperature information transmitted from the first temperature measurement part 213f such that the temperature of the heater 213 becomes a predetermined temperature.

The substrate mounting table 212 is supported by a shaft 217. The shaft 217 is configured to penetrate the bottom portion of the process container 202 and is connected to an elevator mechanism 218 outside the process container 202. By lifting or lowering the shaft 217 and the substrate mounting table 212 through the operation of the elevator mechanism 218, it is possible to lift or lower the wafer 200 mounted on the substrate mounting surface 211. The periphery of the lower end portion of the shaft 217 is covered by a bellows 219, so that the interior of the process chamber 201 is kept airtightly. In addition, the power supply line 213b and the wire 213e are disposed inside the shaft 217.

When transferring the wafer 200, the substrate mounting table 212 is moved down so that the substrate mounting surface 211 is aligned with the position of the substrate loading/unloading gate 1480 (wafer transfer position). When processing the wafer 200, as illustrated in FIG. 1, the wafer 200 is moved up to a processing position (wafer processing position) within the process chamber 201.

Specifically, when the substrate mounting table 212 is moved down to the wafer transfer position, the upper end portions of the lift pins 207 protrude from the upper surface of the substrate mounting surface 211 so that the lift pins 207 support the wafer 200 at the lower side thereof. When the substrate mounting table 212 is moved up to the wafer processing position, the lift pins 207 are retracted from the upper surface of the substrate mounting surface 211 so that the substrate mounting surface 211 supports the wafer 200 at the lower side thereof. Since the lift pins 207 make direct contact with the wafer 200, it is preferred that the lift pins 207 are made of a material such as, for example, quartz or alumina. Alternatively, an elevator mechanism may be installed to the lift pins 207 so that the substrate mounting table 212 and the lift pins 207 can move relative to each other.

### (Exhaust Part)

A first exhaust port 221 as a first exhaust part configured to exhaust an atmosphere of the process chamber 201 is installed on the upper surface of the inner wall of the process chamber 201 (the upper container 202a). An exhaust pipe 224 as a first exhaust pipe is connected to the first exhaust port 221. A pressure regulator 227 such as an APC (Auto Pressure Controller) or the like for controlling the internal pressure of the process chamber 201 to a predetermined pressure and a vacuum pump 223 are sequentially and serially connected to the exhaust pipe 224. A first exhaust part (exhaust line) is mainly configured by the first exhaust port 221, the exhaust pipe 224 and the pressure regulator 227. The vacuum pump 223 may be included in the first exhaust part.

A second exhaust port (shower head exhaust port) 240 as a second exhaust part configured to exhaust an atmosphere of a buffer space 232 is installed on the upper surface of the inner wall of the buffer space 232. An exhaust pipe 236 as a second exhaust pipe is connected to the second exhaust port 240. A valve 237 and the like are sequentially and serially connected to the exhaust pipe 236. A second exhaust part (exhaust line) is mainly configured by the shower head exhaust port 240, the valve 237 and the exhaust pipe 236.

### (Gas Introduction Port)

A gas introduction port 241 for supplying various kinds of gases into the process chamber 201 is installed on the upper surface (ceiling wall) of the upper container 202a. Descriptions will be made later on the configurations of the respective gas supply units connected to the gas introduction port 241 which is a gas supply part. According to the configuration in which the gas is supplied from the center in this way, the gas existing within the buffer space 232 flows from the center toward the outer periphery. It is therefore possible to make the gas flowing within the buffer space 232 uniform, so that the supply amount of the gas to the wafer 200 can be brought into uniformity.

### (Gas Distribution Unit)

A shower head 234 as a gas distribution unit is configured by the buffer chamber (space) 232, the distribution plate 234a as a gas distribution part and the rectifying part 270. The shower head 234 is installed between the gas introduction port 241 and the process chamber 201. A process gas introduced from the gas introduction port 241 is supplied to the buffer space 232 of the shower head 234 and is supplied to the process chamber 201 through distribution holes 234b. The distribution plate 234a and the rectifying part 270, both of which constitute the shower head 234, are made of a heat-resistant material such as, for example, quartz or alumina, or a composite material.

A heater (rectifying part heater) 271 as a second heating part is installed in the rectifying part 270. The heater 271 is configured to heat at least one of the rectifying part 270, the internal atmosphere of the buffer space 232, the distribution plate 234a and the lid 231.

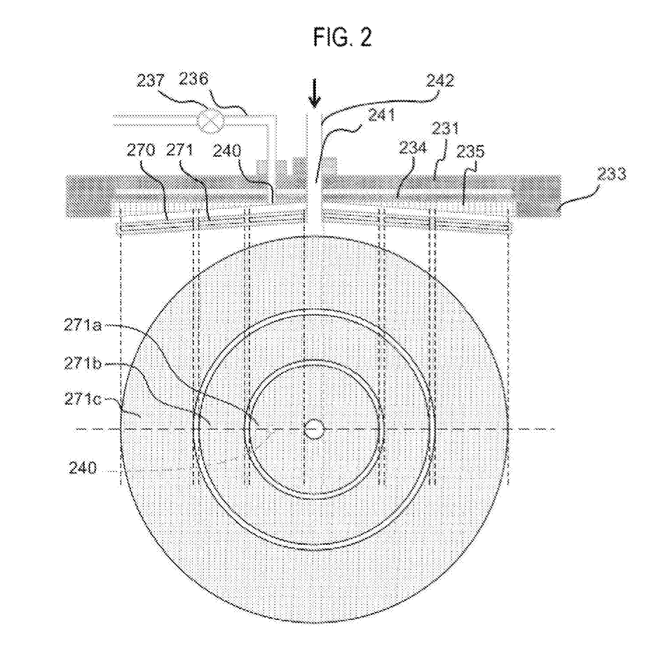

As illustrated in FIG. 2, the heater 271 as the second heating part is divided and is configured to heat individual zones (a central portion 271a, an intermediate portion 271b and a peripheral portion 271c). Preferably, as w ill be described later, the second heating part 271 is controlled so as to increase the temperature of the zone facing the second exhaust port 240. For example, if the zone facing the second exhaust port 240 is the central portion 271a, the second heating part 271 is controlled so as to increase the temperature of the central portion 271a. It is therefore possible to restrain the temperature distribution in the wafer 200 or the temperature distribution in the process chamber 201 from becoming uneven as the heat generated from the heater 213 as the first heating part installed in the substrate support part 210 is dissipated to the outside of the substrate processing apparatus 100 through the second exhaust port 240.

The lid 231 of the shower head 234 may be made of metal having electric conductivity to be used as an activation part (excitation part) for exciting the gas existing within the buffer space 232 or the process chamber 201. In this case, an insulation block 233 is installed between the lid 231 and the upper container 202a to insulate the lid 231 and the upper container 202a from each other. A matcher 251 and a high-frequency power source 252 may be connected to the electrode (the lid 231) as the activation part so as to supply an electromagnetic wave (high-frequency power or microwave).

Preferably, a heat insulator 239 as a heat insulation part is installed between the outer periphery portion 231b of the lid 231 and the outer periphery portion of the distribution plate 234a. By installing the heat insulator 239, it is possible to restrain heat from being transferred from the heater 213 or the second heating part 271 to an upper container seal portion 202c or a lower container seal portion 202d. This makes it possible to suppress deterioration of the upper container seal portion 202c or the lower container seal portion 202d. It is also possible to reduce a difference in thermal expansion between the outer periphery port ion 231b of the lid 231 and the partition plate 204 and to suppress reduction in sealability which may be caused by the difference in thermal expansion. The heat insulator 239 is made of one of quartz, alumina and the like, or a combination thereof.

The shower head 234 has a function of distributing the gas introduced from the gas introduction port 241 between the buffer space 232 and the process chamber 201.

The rectifying part 270 is formed in a conical shape so that the diameter thereof becomes wider as the rectifying part 270 extends outward from the gas introduction port 241 in the radial direction of the wafer 200. The lower end of the outer periphery of the rectifying part 270 is positioned more outward than the end portion of the wafer 200.

FIG. 2 is a view illustrating the second heating part (rectifying part heating body) 271 installed in the rectifying part 270, which is viewed from the side of the wafer 200. As illustrated in FIG. 2, the second heating part 271 is configured by a plurality of zones. The central zone is disposed so as to face the second exhaust port 240 as the second exhaust part and is configured to compensate for heat dissipation from the second exhaust port 240.

A third heating part (lid heating body) 272 is installed in the lid 231 of the shower head 234 and is configured to heat the exhaust flow path 238 of the buffer chamber 232, the upper portion 231a of the lid 231, and the like. A power supply line 2721 is connected to the third heating part 272. A power control part 2722 is connected to the opposite end of the power supply line 2721 from the third heating part 272.

The power control part 2722 as a temperature control part is electrically connected to the controller 260 via a wire 2723. The controller 260 transmits an electric power value for controlling the third heating part 272 to the power control part 2722. The power control part 2722, which has received the electric power value, supplies the electric power corresponding to the information to the third heating part 272, thereby controlling the temperature of the third heating part 272.

A temperature detection part 2724 is installed in the vicinity of the third heating part 272. The temperature detection part 2724 is connected to a third temperature measurement part 2726 via a wire 2725. The temperature of the third heating part 272 can be monitored by the third temperature measurement part 2726.

The temperature (voltage value) measured by the third temperature measurement part 2726 is analog-to-digital converted in the third temperature measurement part 2726, thereby generating temperature data (temperature information). The third temperature measurement part 2726 is electrically connected to the controller 260 and is configured to transmit the generated temperature information to the controller 260. Furthermore, the third temperature measurement part 2726 may be configured to transmit the temperature information to the power control part 2722. The power control part 2722 may be configured to feedback-control the temperature of the third heating part 272 based on the temperature information transmitted from the third temperature measurement part 2726 such that the temperature of the third heating part 272 becomes a predetermined temperature.

Further, the exhaust flow path 238 is configured by the rectifying part 270 and an exhaust guide 235 installed in the lid 231. The lid heating body 272 is configured to heat the exhaust flow path 238 through the lid 231 and the exhaust guide 235.

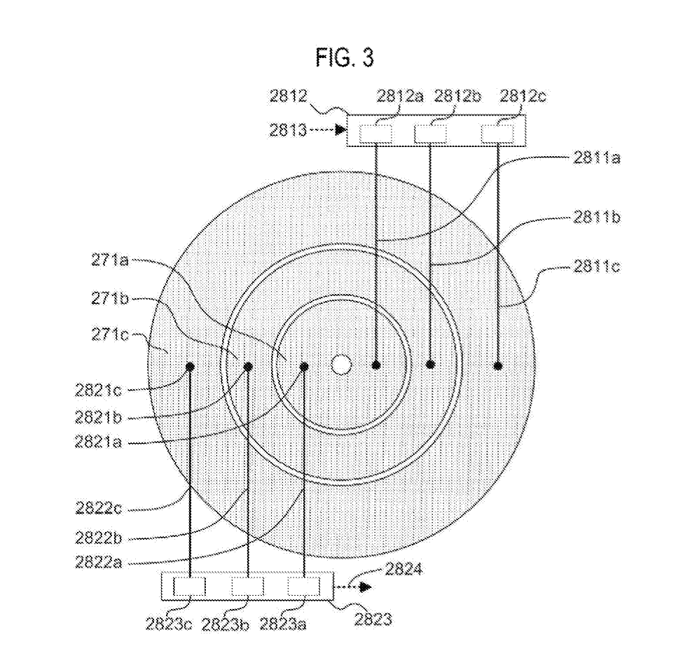

Next, the peripheral configuration of the second heating part 271 will be described with reference to FIG. 3. As illustrated in FIG. 3, power supply lines 2811a, 2811b and 2811c are connected to the respective zones in the second heating part 271 so that the temperature of the second heating part 271 can be controlled on a zone-by-zone basis. The power supply lines 2811a, 2811b and 2811c are connected to a power supply control part 2812 for supplying electric power to the second heating part 271.

Specifically, a power supply line 2811a is connected to the central portion 271a, a power supply line 2811b is connected to the intermediate portion 271b, and a power supply line 2811c is connected to the peripheral portion 271c. Furthermore, the power supply line 2811a is connected to a power supply control part 2812a, the power supply line 2811b is connected to a power supply control part 2812b, and the power supply line 2811c is connected to a power supply control part 2812c.

The power supply control part 2812 as the temperature control part (the power supply control part 2812a, the power supply control part 2812b and the power supply control part 2812c) are electrically connected to the controller 260 via a wire 2813. The controller 260 transmits an electric power value (set temperature data) for controlling the second heating part 271 to the power supply control part 2812. The power supply control part 2812, which has received the electric power value, supplies electric power to the second heating part 271 (the central portion 271a, the intermediate portion 271b and the peripheral portion 271c) based on the information, thereby controlling the temperature of the second heating part 271.

As illustrated in FIG. 3, temperature detection portions 2821a, 2821b and 2821c corresponding to the respective zones are installed in the vicinity of the second hearing part 271. The temperature detection portions 2821a, 2821b and 2821c are connected to temperature measurement part 2823 via wires 2822a, 2822b and 2822c and are configured to detect the temperatures of the respective zones.

Specifically, the temperature detection portion 2821a is installed in the vicinity of the central portion 271a. The temperature detection portion 2821a is connected to a second temperature measurement portion 2823a via the wire 2822a. A temperature detection portion 2821b is installed in the vicinity of the intermediate portion 271b. The temperature detection portion 2821b is connected to a second temperature measurement portion 2823b via the wire 2822b. A temperature detection portion 2821c is installed in the vicinity of the peripheral portion 271c. The temperature detection portion 2821c is connected to a second temperature measurement portion 2823c via the wire 2822c.

The respective second temperature measurement part 2823 (the second temperature measurement portion 2823a, the second temperature measurement portion 2823b and the second temperature measurement portion 2823c) monitors (measures) the temperatures of the corresponding zones via the temperature detection part (the temperature detection portion 2821a, the temperature detection portion 2821b and the temperature detection portion 2821c) and the wires (the wire 2822a, the wire 2822b and the wire 2822c). The temperatures (voltage values) measured by the second temperature measurement part 2823 are analog-to-digital converted in the second temperature measurement part 2823, thereby generating temperature data (temperature information). The temperature information thus generated can be transmitted to the controller 260 via a wire 2824.

A temperature detection part 2341 is installed on the surface 234c of the distribution plate 234a, which faces the rectifying part 270. The temperature detection part 2341 is connected to a fourth temperature measurement part 2343 via a wire 2342.

The fourth temperature measurement part 2343 measures the temperature of the surface 234c. The temperature (voltage value) measured by the fourth temperature measurement part 2343 is analog-to-digital converted in the fourth temperature measurement part 2343, thereby generating temperature data (temperature information). The fourth temperature measurement part 2343 is electrically connected to the controller 260 and is configured to transmit the generated temperature information to the controller 260.

A temperature detection part 2345 is installed on the surface 234d of the distribution plate 234a, which faces the substrate mounting surface 211. The temperature detection part 2345 is connected to a temperature measurement part 2347 via a wire 2346.

The temperature measurement part 2347 measures the temperature of the surface 234d. The temperature (voltage value) measured by the temperature measurement part 2347 is analog-to-digital converted in the temperature measurement part 2347, thereby generating temperature data (temperature information). The temperature measurement part 2347 is electrically connected to the controller 260 and is configured to transmit the generated temperature information to the controller 260.

### (Process Gas Supply Part)

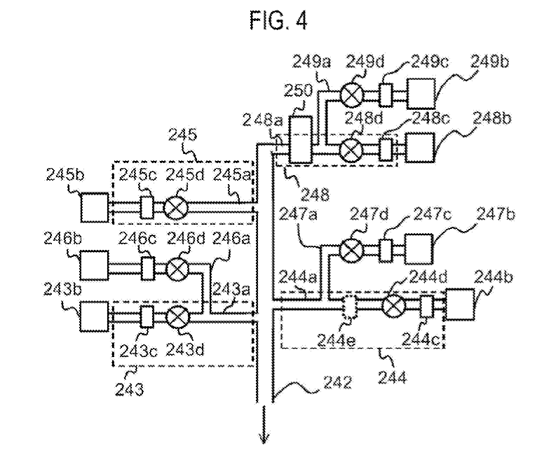

A common gas supply pipe 242 is connected to the gas introduction port 241 connected to the rectifying part 270. As illustrated in FIG. 4, a first gas supply pipe 243a, a second gas supply pipe 244a, a third gas supply pipe 245a and a cleaning gas supply pipe 248a are connected to the common gas supply pipe 242.

A first-element-containing gas (first process gas) is mainly supplied from a first gas supply part 243 including the first gas supply pipe 243a. A second-element-containing gas (second process gas) is mainly supplied from a second gas supply part 244 including the second gas supply pipe 244a. A purge gas is mainly supplied from a third gas supply part 245 including the third gas supply pipe 245a. A cleaning gas is supplied from a cleaning gas supply part 248 including the cleaning gas supply pipe 248a. The process gas supply part for supplying the process gas is configured by one or both of a first process gas supply part and a second process gas supply part. The process gas is composed of one or both of a first process gas and a second process gas.

### (First Gas Supply Part)

A first gas supply source 243b, a mass flow controller (MFC) 243c, which is a flow rate controller (flow rate control part), and a valve 243d, which is an opening/closing valve, are installed in the first gas supply pipe 243a sequentially from the upstream side.

A first-element-containing gas (first process gas) is supplied from the first gas supply source 243b and is supplied to the buffer space 232 via the mass flow controller 243c, the valve 243d, the first gas supply pipe 243a and the common gas supply pipe 242.

The first process gas is a precursor gas, namely one of the process gases. In this regard, a first element is, for example, silicon (Si). That is to say, the first process gas is, for example, a silicon-containing gas. As the silicon-containing gas, it may be possible to use, for example, a dichlorosilane (SiH₂ Cl₂ ; DCS) gas. The precursor of the first process gas may be any one of a solid, a liquid and a gas under room temperature and atmospheric pressure. If the precursor of the first process gas is a liquid under room temperature and atmospheric pressure, a vaporizer not shown may be installed between the first gas supply source 243b and the mass flow controller 243c. In the present embodiment, descriptions will be made under the assumption that the precursor is a gas.

The downstream end of a first inert gas supply pipe 246a is connected to the first gas supply pipe 243a at the downstream side of the valve 243d. An inert gas supply source 246b, a mass flow controller (MFO) 246c, which is a flow rate controller (flow rate control part), and a valve 246d, which is an opening/closing valve, are installed in the first inert gas supply pipe 246a sequentially from the upstream side.

In the present embodiment, the inert gas is, for example, a nitrogen (N₂) gas. As the inert gas, in addition to the N₂ gas, it may be possible to use, for example, a rare gas such as a helium (He) gas, a neon (Ne) gas, an argon (Ar) gas or the like.

A first-element-containing gas supply part 243 (also referred to as a silicon-containing gas supply part) is mainly configured by the first gas supply pipe 243a, the mass flow controller 243c and the valve 243d.

Furthermore, a first inert gas supply part is mainly configured by the inert gas supply pipe 246a, the mass flow controller 246c and the valve 246d. The inert gas supply source 246b and the fist gas supply pipe 243a may be included in the first inert gas supply part.

In addition, the first gas supply source 243b and the first inert gas supply part may be included in the first-element-containing gas supply part.

### (Second Gas Supply Part)

A second gas supply source 244b, a mass flow controller (MFC) 244c, which is a flow rate controller (flow rate control part), and a valve 244d, which is an opening/closing valve, are installed in the upstream portion of the second gas supply pipe 244a sequentially from the upstream side.

A second-element-containing gas (hereinafter referred to as a “second process gas”) is supplied from the second gas supply source 244b and is supplied to the buffer space 232 via the mass flow controller 244c, the valve 244d, the second gas supply pipe 244a and the common gas supply pipe 242.

The second process gas is one of the process gases. The second process gas may be regarded as a reaction gas or a modification gas.

In the present embodiment, the second process gas contains a second element differing from the fist element. The second element includes, for example, one or more of oxygen (O), nitrogen (N), carbon (C) and hydrogen (H). In the present embodiment, it is assumed that the second process gas is, for example, a nitrogen-containing gas. Specifically, as the nitrogen-containing gas, an ammonia (NH₃) gas is used.

A second process gas supply part 244 is mainly configured by the second gas supply pipe 244a, the mass flow controller 244c and the valve 244d.

In addition, a remote plasma unit (RPU) 244e as an activation part may be installed to activate the second process gas.

The downstream end of a second inert gas supply pipe 247a is connected to the second gas supply pipe 244a at the downstream side of the valve 244d. An inert gas supply source 247b, a mass flow controller (MFC) 247c, which is a flow rate controller (flow rate control part), and a valve 247d, which is an opening/closing valve, are installed in the second inert gas supply pipe 247a sequentially from the upstream side.

An inert gas is supplied from the second inert gas supply pipe 247a to the buffer space 232 via the mass flow controller 247c, the valve 247d and the second inert gas supply pipe 247a. The inert gas acts as a carrier gas or a dilution gas in a thin film forming process (S203 to S207 described later).

A second inert gas supply part is mainly configured by the second inert gas supply pipe 247a, the mass flow controller 247c and the valve 247d. The inert gas supply source 247b and the second gas supply pipe 244a may be included in the second inert gas supply part.

In addition, the second gas supply source 244b and the second inert gas supply part may be included in the second-element-containing gas supply part 244.

### (Third Gas Supply Part)

A third gas supply source 245b, a mass flow controller (MFC) 245c, which is a flow rate controller (flow rate control part), and a valve 245d, which is an opening/closing valve, are installed in the third gas supply pipe 245a sequentially from the upstream side.

An inert gas as a purge gas is supplied from the third gas supply source 245b and is supplied to the buffer space 232 via the mass flow controller 245c, the valve 245d, the third gas supply pipe 245a and the common gas supply pipe 242.

In the present embodiment, the inert gas is, for example, a nitrogen (N₂) gas. As the inert gas, in addition to the N₂ gas, it may be possible to use, for example, a rare gas such as a helium (He) gas, a neon (Ne) gas, an argon (Ar) gas or the like.

A third gas supply part 245 (also referred to as a purge gas supply part) is mainly configured by the third gas supply pipe 245a, the mass flow controller 245c and the valve 245d.

### (Cleaning Gas Supply Part)

A cleaning gas source 248b, a mass flow controller (MFC) 248c, a valve 248d and a remote plasma unit (RPU) 250 are installed in the cleaning gas supply pipe 248a sequentially from the upstream side.

A cleaning gas is supplied from the cleaning gas source 248b and is supplied to the buffer space 232 via the MFC 248c, the valve 248d, the RPU 250, the cleaning gas supply pipe 249a and the common gas supply pipe 242.

The downstream end of a fourth inert gas supply pipe 249a is connected to the cleaning gas supply pipe 248a at the downstream side of the valve 248d. A fourth inert gas supply source 249b, a MFC 249c and a valve 249d are installed in the fourth inert gas supply pipe 249a sequentially from the upstream side.

A cleaning gas supply part is mainly configured by the cleaning gas supply pipe 248a, the MFC 248c and the valve 248d. The cleaning gas source 248b, the fourth inert gas supply pipe 249a and the RPU 250 may be included in the cleaning gas supply part.

The inert gas supplied from the fourth inert gas supply source 249b may be supplied so as to act as a carrier gas or a dilution gas of the cleaning gas.

The cleaning gas supplied from the cleaning gas supply source 248b acts to remove a byproduct or the like adhering to the buffer space 232 or the process chamber 201 in the cleaning process.

In the present embodiment, the cleaning gas is, for example, a nitrogen trifluoride (NF₃) gas. As the cleaning gas, it may be possible to use, for example, a hydrogen fluoride (HF) gas, a chlorine trifluoride gas (CIF₃) gas, a fluorine (F₂) gas or the like. These gases may be used in combination.

Preferably, the flow rate control part installed in each of the gas supply parts described above may be a flow rate control part having a high responsiveness to a gas flow, such as a needle valve, an orifice or the like. For example, if the pulse width of a gas is of a millisecond order, there may be a case where the MFC cannot respond thereto. The needle valve or the orifice, when combined with a high-speed on/off valve, can cope with a gas pulse of milliseconds or less.

### (Control Part)

As illustrated in FIG. 1, the substrate processing apparatus 100 includes the controller 260 configured to control the operations of the respective parts of the substrate processing apparatus 100.

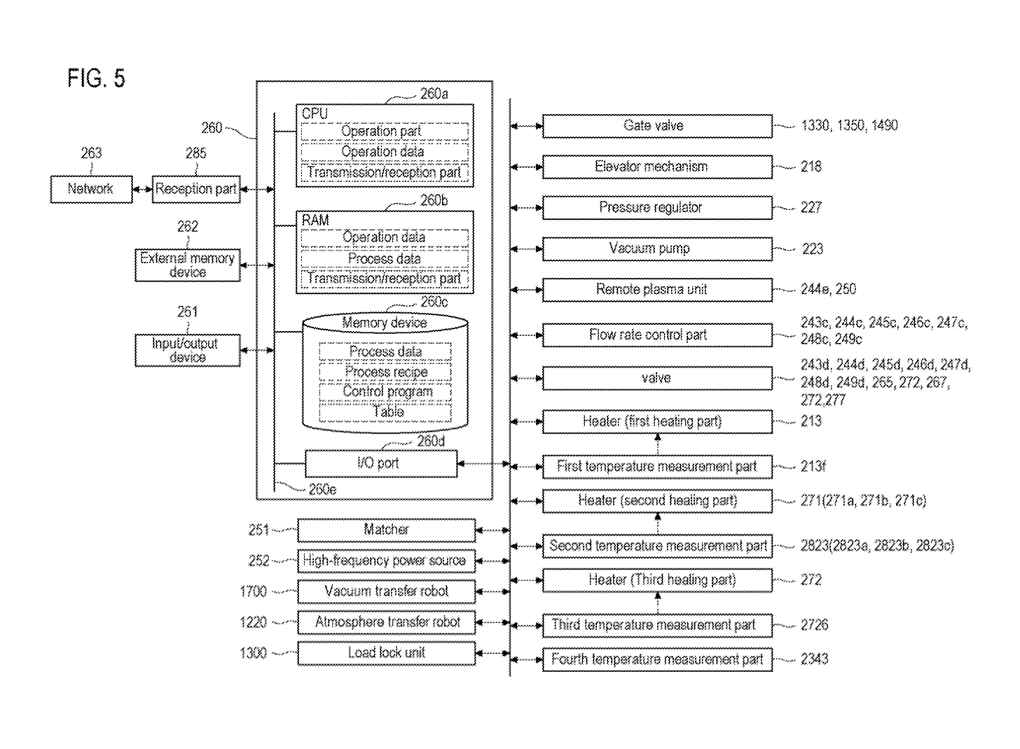

The outline of the controller 260 is illustrated in FIG. 5. The controller 260, which is a control part (control means), is configured as a computer which includes a CPU (Central Processing Unit) 260a as an operation part, a RAM (Random Access Memory) 260b, a memory device 260c and an I/O port 260d. The RAM 260b, the memory device 260c and the I/O port 260d are configured to exchange data with the CPU 260a via an internal bus 260c. For example, the controller 260 is configured such that an input/output device 261 configured with a touch panel or the like and an external memory device 262 are connectable thereto.

The memory device 260c is configured by, for example, a flash memory, a HDD (Hard Disk Drive), or the like. A control program for controlling the operation of the substrate processing apparatus, a process recipe in which a sequence, condition, or the like for a film forming process to be described later is written, process data used in an operation process until a process recipe is set with respect to the wafer 200, a table which stores control conditions, and the like, are readably stored in the memory device 260c. The process recipe is a combination to cause the controller 260 to execute each sequence in the film forming process which will be described later, so as to obtain a predetermined result, and functions as a program. Hereinafter, the process recipe and the control program will be generally and simply referred to as a “program.” When the term “program” is used herein, it may indicate a case of including only the process recipe, a case of including only the control program, or a case of including both the process recipe and the control program. The RAM 260b is configured as a memory area (work area) in which a program, operation data, process data and the like read by the CPU 260a are temporarily stored.

The I/O port 260d is connected to the gate valves 1330, 1350 and 1490, the elevator mechanism 218, the heater 213, the pressure regulator 227, the vacuum pump 223, the remote plasma unit 244e and 250, the MFCs 243c, 244c, 245c, 246c, 247c, 248c and 249c, the valves 243d, 244d, 245d, 246d, 247d, 248d and the like. Furthermore, the I/O port 260d is connected to the matcher 251, the high-frequency power source 252, a transfer robot 1700, a atmosphere transfer robot 1220, a load lock unit 1300, and the like.

The CPU 260a as an operation part is configured to read the control program from the memory device 260c and to execute the same. The CPU 260a is also configured to read the process recipe from the memory device 260c and in response to an operation command inputted from the input/output device 261. Furthermore, the CPU 260a is configured to calculate operation data by performing a comparison operation upon the set values inputted from the reception part 285 with the process recipe or the control data stored in the memory device 260c. Moreover, the CPU 260a is configured to execute a process of determining the corresponding process data (process recipe) from the operation data. In addition, the CPU 260a is configured to control, according to the contents of the read process recipe, the opening/closing operation of the gate valves 1330, 1350 and 1490, the elevating operation of the elevator mechanism 218, the pressure regulation operation of the pressure regulator 227, the on/off operation of the vacuum pump 223, the gas excitation operation of the remote plasma unit 250, the flow rate control operation of the MFCs 243c, 244c, 245c, 246c, 247c, 248c and 249c, the gas on/off operation of the valves 243d, 244d, 245d, 246d, 247d, 248d and 249d, the temperature control operation of the heaters 213, 271 and 272, and the like.

The controller 260 is not limited to being configured as a dedicated computer but may be configured as a general-purpose computer. For example, the controller 260 according to the present embodiment may be configured by preparing an external memory device 262 (e.g., a magnetic tape, a magnetic disc such as a flexible disc or a hard disc, an optical disc such as a CD or a DVD, a magneto-optical disc such as an MO or the like, or a semiconductor memory such as a USB memory, a memory card or the like), which stores the program, and installing the program in a general-purpose computer using the external memory device 262. The means for supplying the program to the computer is not limited to that of supplying the program via the external memory device 262. For example, the program may be supplied via a reception part 285 through the use of a communication means such as a network 263 (the Internet or a dedicated line) or the like without intervention of the external memory device 262. The memory device 260c or the external memory device 262 is configured as a computer-readable recording medium. Hereinafter, the memory device 260c and the external memory device 262 will be generally and simply referred to as a “recording medium.” When the term “recording medium” is used herein, it may indicate a case of including only the memory device 260c, a case of including only the external memory device 262, or a case of including both the memory device 260c and the external memory device 262.

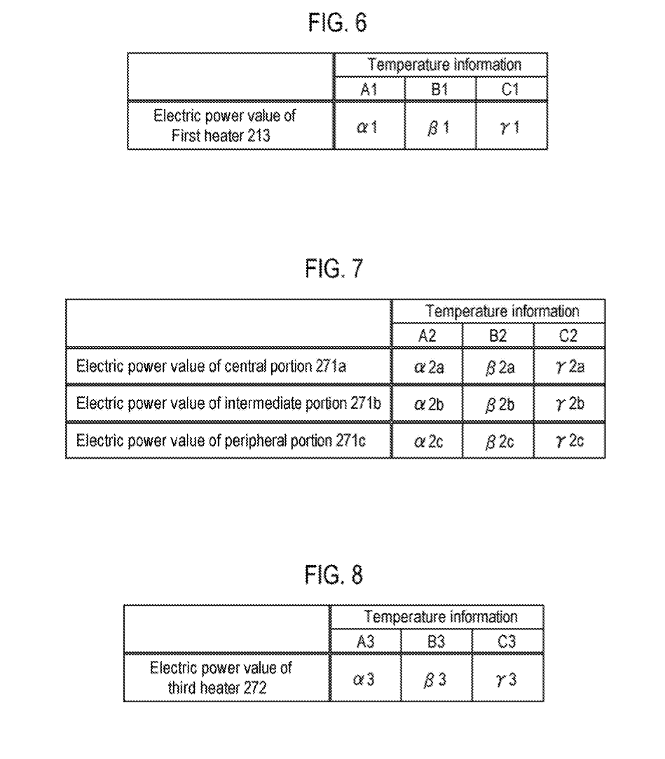

Tables corresponding to the first heater 213, the second heater 271 and the third heater 272 are recorded. Specifically, a first table illustrated in FIG. 6, a second table illustrated in FIG. 7, and a third table illustrated in FIG. 8, are recorded.

In the first table, the temperature information A1, B1 and C1 measured by the temperature measurement part are compared with the electric power values supplied to the first heater 213. The temperature information in this table is measured by, for example, the first temperature measurement part 213f or the temperature measurement part 2347. In this case, the temperature information may be information, which is measured by one of the temperature measurement parts or which is calculated by adding information measured by both of the temperature measurement parts.

When using the first table, for example, if the temperature information A1 is detected, the controller 260 instructs the power control part 213c to supply an electric power value α1 to the first heating part 213. This holds true in the case of other temperature information B1 and C1.

In the second table, the temperature information A2, B2 and C2 measured by the temperature measurement part 2823 are compared with the electric power values supplied to the second heater 271. The temperature information in this table is measured by, for example, the temperature measurement part 2823 or the fourth temperature measurement part 2343. In this case, the temperature information may be information measured by one of the temperature measurement parts or detection values calculated by adding information measured by both of the temperature measurement parts.

When using the second table, for example, if the temperature information A2 is detected, the controller 260 instructs the power control part 2812a to supply an electric power value α2αto the central portion 271a of the second heating part, instructs the power control part 2812b to supply an electric power value α2b to the intermediate portion 271b of the second heating part, and instructs the power supply control part 2812c to supply an electric power value α2c to the peripheral portion 271c of the second heating part. This holds true in the case of other temperature information B2 and C2.

In the third table, the temperature information A3, B3 and C3 detected by the temperature measurement part 2726 are compared with the electric power values supplied to the third heater 272. The temperature information in this table is measured by, for example, the temperature measurement part 2726 or the fourth temperature measurement part 2343. In this case, the temperature information may be information measured by one of the temperature measurement parts or detection values calculated by adding information measured by both of the temperature measurement parts.

When using the third table, for example, if the temperature information A3 is detected, the controller 260 instructs the power control part 2722 to supply an electric power value α3 to the third heater 272. This holds true in the case of other temperature information B3 and C3.

### (2) Substrate Processing Process

Next, one example of a substrate processing process will be described based on an example in which a silicon nitride (SiₓN_{y}) film is formed using a DCS gas and an NH₃ (ammonia) gas, which is use in one of the processes of manufacturing a semiconductor device. In the following descriptions, the operations of the respective parts that constitute the substrate processing apparatus are controlled by the controller 260.

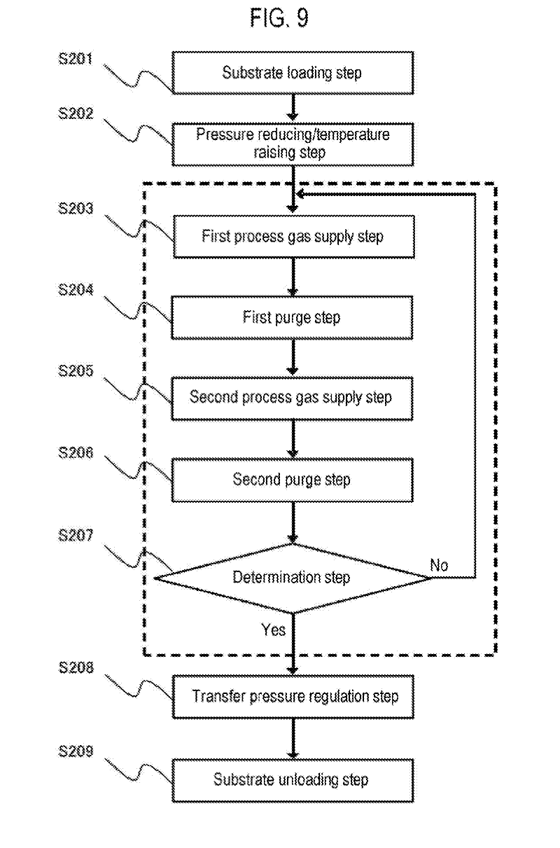

FIG. 9 illustrates a flow of a substrate processing process in the ease where a silicon nitride (SiₓN_{y}) film is formed on a wafer 200 as a substrate.

### (Substrate Loading Step S201)

In a film forming process, a wafer 200 is first loaded into the process chamber 201. Specifically, the substrate support part 210 is moved down by the elevator mechanism 218 so that the lift pins 207 protrude toward the upper side of the substrate support part 210 from the through-holes 214. After the internal pressure of the process chamber 201 is regulated to a predetermined pressure, the gate valve 1490 is opened and the wafer 200 is mounted on the lift pins 207. After the wafer 200 is mounted on the lift pins 207, the substrate support part 210 is moved up to a predetermined position by the elevator mechanism 218, whereby the wafer 200 is transferred from the lift pins 207 to the substrate support part 210. The substrate support part 210 may be moved up to a position where the protrusion portion 212b of the substrate mounting table 212 makes contact with (bumps against) the partition plate 204.

At this time, the substrate mounting table 212 may be heated in advance by the heater 213. By heating the substrate mounting table 212 in advance, it is possible to shorten the heating time of the wafer 200. When the wafer 200 is transferred from the lift pins 207 to the substrate mounting surface 211, if the wafer 200 is bounded upward or if the wafer 200 warps, the wafer 200 may be preheated. The preheating may be performed inside the substrate processing apparatus 100 or may be performed outside the substrate processing apparatus 100. For example, when the preheating is performed inside the substrate processing apparatus 100, the wafer 200 is heated for a predetermined waiting time in a state in which the wafer 200 is supported by the lift pins 207, by setting the distance between, the substrate mounting table 212 and the wafer 200 at a predetermined first distance. In this case, the first distance may be a distance to the wafer transfer position where the wafer 200 is transferred from the gate valve 1490. The first distance may be shorter than the distance to the wafer transfer position. The heat-up time when preheating the wafer 200 inside the substrate processing apparatus 100 is changed depending on the distance between the wafer 200 and the substrate mounting table 212. By setting the distance to become shorter, it is possible to shorten the heat-up time. Specifically, the substrate mounting table 212 is heated in advance and is retained for a certain period of time after the temperature change of the wafer 200 or the susceptor disappears. At this time, an inert gas may be supplied from the third gas supply part 245 and the wafer 200 may be moved up to a predetermined position while heating the wafer 200 by the second heating part 271 installed in the rectifying part 270. By heating the wafer 200 with the second heating part 271, it is possible to control a warping amount of the wafer 200 or suppress the wafer 200 from bouncing.

At this time, the temperatures of the respective heating parts are controlled based on the temperature information detected by the respective temperature measurement parts. For example, the temperatures of the respective heating parts are set as follows. The temperature of the heater 213 is set at a certain temperature which falls within a range of 400 to 850 degrees C., preferably 400 to 800 degrees C., more preferably 400 to 750 degrees C. The heating of the wafer 200 or the heating of the substrate mounting table 212 using the heater 213 is continuously performed, for example, at a repetition process up to step S207. The temperature of the second heating part 271 is set to become equal to the temperature of the heater 213. The temperature of the lid heating body 272 is set at a certain temperature which falls within a range of about 250 to 400 degrees C. The temperatures of the respective zones of the second heating part 271 are set such that the temperature of the zone facing the second exhaust port 240 becomes higher. For example, if the zone facing the second exhaust port 240 is the central portion 271a, the second heating part 271 is controlled so as to make the temperature of the central portion 271a higher. Specifically, the temperature of the central portion 271a is set higher than the temperature of the peripheral portion 271c which is set higher than the temperature of the intermediate portion 271b. Furthermore, it is preferred that the temperatures of the respective zones of the second heating part 271 are set equal to or lower than the temperature at which one or both of the first process gas and the second process gas (reaction gas) are decomposed. By setting the temperatures, of the respective zones of the second heating part 271 to become equal to or lower than the temperature at which one or both of the process gas and the reaction gas are decomposed, it is possible to suppress film formation on the rectifying part 270.

### (Pressure Reducing/Temperature Raising Step S202)

Subsequently, the interior of the process chamber 201 is exhausted through the exhaust pipe 224 such that the internal pressure of the process chamber 201 reaches a predetermined pressure (vacuum degree). At this time, the valve opening degree of the APC valve as the pressure regulator 227 is feedback-controlled based on the pressure value measured by a pressure sensor. Furthermore, the amount of electric power supplied to the heater 213 is feedback-controlled based on the temperature value detected by a temperature sensor (not shown) such that the internal temperature of the process chamber 201 reaches a predetermined temperature. A process of removing the moisture remaining within the process chamber 201 or a gas generated from a member by the vacuum exhaust or by the purge through the supply of an N₂ gas, may be provided until the temperature of the wafer 200 becomes constant. Thus, the preparation before the film forming process is completed. When exhausting the interior of the process chamber 201 to a predetermined pressure, the interior of the process chamber 201 may be vacuum exhausted up to a reachable vacuum degree at one time.

### (First Process Gas Supply Step S203)

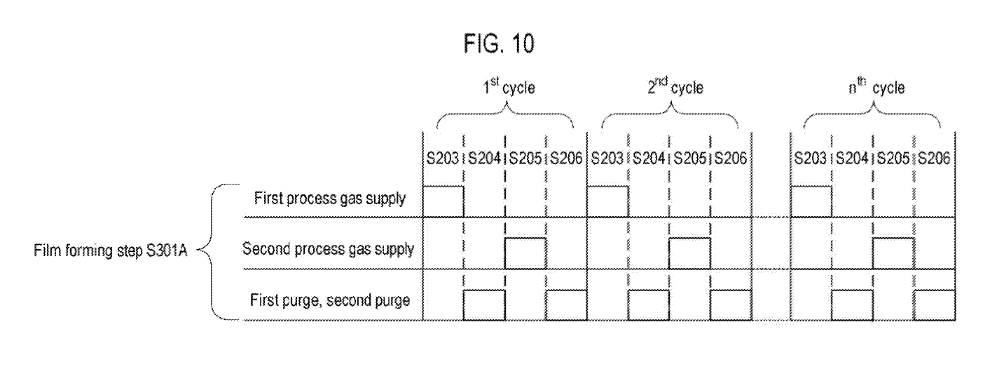

Subsequently, as illustrated in FIG. 10, a DCS gas as a first process gas (precursor gas) is supplied from the first process gas supply part into the process chamber 201. By continuously performing the exhaust of the interior of the process chamber 201 with the exhaust part, the internal pressure of the process chamber 201 is controlled so as to reach a predetermined pressure (first pressure). Specifically, the valve 243d of the first gas supply pipe 243a and the valve 246d of the first inert gas supply pipe 246a are opened to allow a DCS gas to flow through the first gas supply pipe 243a while allowing an N₂ gas to flow through the first inert gas supply pipe 246a. The flow rate of the DCS gas flowing through the first gas supply pipe 243a is adjusted to a predetermined flow rate by the MFC 243c. The flow rate of the N₂ gas flowing through the first inert gas supply pipe 246a is adjusted to a predetermined flow rate by the MFC 246c. The flow-rate-adjusted DCS gas and the flow-rate-adjusted N₂ gas are mixed within the first gas supply pipe 243a. The mixed DCS gas and the N₂ gas are supplied from the buffer space 232 into the process chamber 201 and are exhausted from the exhaust pipe 224. At this time, the DCS gas is supplied to the wafer 200 (precursor gas (DCS) supply step). The DCS gas is supplied into the process chamber 201 at a predetermined pressure (first pressure of. e.g., 100 Pa or more and 10000 Pa or less). In this way, DCS is supplied to the wafer 200. By supplying the DCS gas, a silicon-containing layer is formed on the wafer 200, The silicon-containing layer is a layer which contains silicon (Si) or a layer which contains silicon and chlorine (CI).

### (First Purge Step S204)

After the silicon-containing layer is formed on the wafer 200, the valve 243d of the first gas supply pipe 243a is closed to stop the supply of the DCS gas. At this time, while opening the pressure regulator 227 of the exhaust pipe 224, the interior of the process chamber 201 is vacuum exhausted by the vacuum pump 223, whereby the DCS gas remaining within the process chamber 201, the unreacted DCS gas or the DCS gas contributed to the formation of the silicon-containing layer is discharged from the interior of the process chamber 201. Furthermore, while opening the valve 246d, the supply of the N₂ gas as an inert gas into the process chamber 201 may be maintained. The N₂ gas continuously supplied from the valve 246a acts as a purge gas. This makes it possible to further enhance the effect of discharging the unreacted DCS gas or the DCS gas contributed to the formation of the silicon-containing layer, which remains within the first gas supply pipe 243a, the common gas supply pipe 242 and the process chamber 201.

At this time, the gas remaining within the process chamber 201 or the buffer space 232 may not be completely discharged (the interior of the process chamber 201 may not be completely purged). If the amount of the gas remaining within the process chamber 201 is small, the gas does not adversely affect the step performed thereafter. At this time, the flow rate of the N₂ gas supplied into the process chamber 201 need not be set at a large flow rate. For example, by supplying the N₂ gas in an amount substantially equal to the volume of the process chamber 201, it is possible to perform the purge so as not to adversely affect the next step. If the interior of the process chamber 201 is not completely purged in this way, it is possible to shorten the purge time and to improve the throughput. In addition, it is possible to suppress the consumption of the N₂ gas to a necessary minimum level.

At this time, the temperature of the heater 213 is set in the same manner as when the precursor gas is supplied to the wafer 200. The supply flow rates of the N₂ gas as a purge gas supplied from the respective inert gas supply parts are respectively set to fall within a range of, e.g., 100 to 20000 sccm. As the purge gas, in addition to the N ₂ gas, it may be possible to use a rare gas such as an Ar gas, a He gas, a Ne gas, a Xe gas or the like.

At this time, the valve 237 of the second exhaust part may be opened so that the unreacted DCS gas or the DCS gas contributed to the formation of the silicon-containing layer, which remains within the buffer space 232 or the common gas supply pipe 242, is exhausted via the exhaust flow path 238, the exhaust pipe 236 and the like. By exhausting the internal atmosphere of the buffer space 232 or the common gas supply pipe 242 from the exhaust flow path 238 or the exhaust pipe 236, it is possible to decrease the supply of the remaining unreacted DCS gas or the DCS gas contributed to the formation of the silicon-containing layer to the process chamber 201 (the wafer 200). In addition, the exhaust from the second exhaust part may be performed before and/or after the first purge step or may be performed simultaneously with the fist purge step.

### (Second Process Gas Supply Step S205)

After the DCS gas remaining within the process chamber 201 is removed, the supply of the purge gas is stopped and an NH₃ gas as a reaction gas is supplied. Specifically, the valve 244d of the second gas supply pipe 244a is opened to allow the NH₃ gas to flow through the second gas supply pipe 244a. The flow rate of the NH₃ gas flowing through the second gas supply pipe 244a is adjusted by the MFC 244c. The flow-rate-adjusted NH₃ gas is supplied to the wafer 200 via the common gas supply pipe 242 and the buffer space 232. The NH₃ gas supplied onto the wafer 200 reacts with the silicon-containing layer formed on the wafer 200, thereby nitriding silicon and discharging impurities such as hydrogen, chlorine, hydrogen chloride or the like.

At this time, the temperature of the heater 213 is set in the same manner of supplying the precursor gas to the wafer 200.

### (Second Purge Gas Step S206)

After the second process gas supply step, the supply of the reaction gas is stopped and the same process as that of the first purge step S204 is performed . By performing the residual gas removal step, it is possible to discharge the unreacted NH₃ gas contributed to the nitriding of silicon, which remains within the second gas supply pipe 244a, the common gas supply pipe 242, the buffer space 232, the process chamber 201 and the like. By removing the residual gas, it is possible to suppress unexpected film formation otherwise caused by the residual gas.

At this time, the valve 237 of the second exhaust part may be opened so that the unreacted DCS gas or the DCS gas contributed to the formation of the silicon-containing layer, which remains within the buffer space 232 or the common gas supply pipe 242, is exhausted via the exhaust flow path 238, the exhaust pipe 236 and the like. By exhausting the internal atmosphere of the buffer space 232 or the common gas supply pipe 242 from the exhaust flow path 238 or the exhaust pipe 236, it is possible to decrease the supply of the remaining unreacted DCS gas or the DCS gas contributed to the formation of the silicon-containing layer to the process chamber 201 (the wafer 200). In addition, the exhaust from the second exhaust part

may be performed before and/or after the first purge step or may be performed simultaneously with the first purge step.

### (Determination Step (Repetition Step) S207)

By performing each of the first process gas supply step S203, the first purge step S204, the second process gas supply step S205 and the second purge step S206 at once, a silicon nitride (Siₓ N_{y} ) layer having a predetermined thickness is deposited on the wafer 200. By repeating these steps, it is possible to control the thickness of a silicon nitride film formed on the wafer 200. The aforementioned steps are controlled so as to be repeated a predetermined number of times until the thickness of the silicon nitride film reaches a predetermined thickness.

### (Transfer Pressure Regulation Step S208)

After performing step S203 to step S207 a predetermined number of times, a transfer pressure regulation step S208 is performed to unload the wafer 200 from the process chamber 201. Specifically, an inert gas is supplied into the process chamber 201 to regulate the internal pressure of the process chamber 201 to a pressure at which the wafer 200 can be transferred.

### (Substrate Unloading Step S209)

After the pressure regulation, the substrate support part 210 is moved down by the elevator mechanism 218. The lift pins 207 protrude from the through-holes 214 and the wafer 200 is mounted on the lift pins 207. After the wafer 200 is mounted on the lift pins 207, the gate valve 1490 is opened and the wafer 200 is unloaded from the process chamber 201. Prior to unloading the wafer 200, the temperature of the wafer 200 may be lowered to a temperature at which the wafer 200 can be unloaded.

### (3) Effects According To The Present Embodiment

According to the present embodiment, one or more of the following effects (a) to (f) may be achieved.

(a) By installing the second heating part and heating the distribution plate 234a, it is possible to suppress the radiation of heat from the distribution plate 234a, thereby improving the temperature uniformity of the wafer 200. Furthermore, it is possible to reduce the power consumption of the first heating part (the heater 213).

(b) By dividing the second heating part into a plurality of zones and setting the temperature of the zone facing the second exhaust port to become higher than the temperature of other zones, it is possible to suppress the heat transfer to the second exhaust port, thereby improving the temperature uniformity of the wafer 200.

(c) It is possible to reduce a temperature difference of the distribution plate 234a and to suppress generation of a thermal stress in the distribution plate 234a. It is also possible to suppress separation of a film adhering to the distribution plate 234a.

(d) It is possible to suppress generation of a thermal stress otherwise caused by a temperature difference of the rectifying part 270 and to suppress separation of a film from the rectifying part 270.

(e) It is possible to suppress generation of a thermal stress otherwise caused by the temperature of the exhaust guide 235 and to suppress separation of a film from the exhaust guide 235.

(f) By installing the heat insulator 239 as a heat insulation part between the outer periphery portion 231b of the lid 231 and the distribution plate 234a and the insulation block 233, it is possible to suppress the heat transfer from the distribution plate 234a toward the outer periphery of the distribution plate 234a (in the radial direction), thereby improving the temperature uniformity of the shower head 234. It is also possible to suppress the heat transfer from the heater 213 or the second heating part 271 toward the upper container seal portion 202c or the lower container seal portion 202d. This makes it possible to suppress deterioration of the upper container seal portion 202c or the lower container seal portion 202d. It is also possible to reduce the difference in heat expansion between the outer periphery portion 231b of the lid 231 and the partition plate 204, thereby suppressing reduction of the sealability otherwise caused by the difference in heat expansion.

While the method of forming a film by alternately supplying the precursor gas and the reaction gas has been described above, other methods may be used as long as the gas phase reaction amount of the precursor gas and the reaction gas or the generation amount of the byproduct falls within a permissible range. For example, it may be possible to use a method in which the supply timings of the precursor gas and the reaction gas overlap with each other.

While the film forming process has been described above, the present disclosure may be applied to other processes. Examples of other processes include a diffusion process, an oxidation process, a nitriding process, an oxynitriding process, a reduction process, an oxidation-reduction process, an etching process, a heating process and the like. For example, the present disclosure may be applied to a case where a substrate surface or a film formed on a substrate is subjected to a plasma oxidation process or a plasma nitriding process using only a reaction gas. Furthermore, the present disclosure may be applied to a plasma annealing process which is performed using only a reaction gas.

While the substrate processing process has been described above, the present disclosure is not limited thereto. The present disclosure may be applied to a cleaning process performed by a substrate processing apparatus. For example, when a cleaning gas is supplied to the shower head 234, if a temperature difference is generated between the respective zones of the rectifying part heater 271, it is possible to improve the removal efficiency of a film or an extraneous material adhering to the rectifying part 270.

While the semiconductor device manufacturing process has been described above, the present disclosure may be applied to processes other than the semiconductor device manufacturing process. Examples of other processes include a liquid crystal display manufacturing process, a plasma processing process of a ceramic substrate and the like.

While the example in which the silicon nitride film is formed using the silicon-containing gas and the nitrogen-containing gas as precursor gases has been described above, the present disclosure may be applied to film formation that makes use of other gases. Examples of films formed using other gases include an oxygen-containing film, a nitrogen-containing film, a carbon-containing film, a boron-containing film, a metal-containing film and films containing these elements. Specific examples of these films include an SiO film, an AlO film, a ZrO film, an HfO film, an HfAlO film, a ZrAlO film, an SiC film, an SiCN film, an SiBN film, a TiN film, a TiC film, a TiAlC film and the like. If the supply position or the internal structure of the shower head 234 is appropriately changed by comparing the gas properties (an adsorption property, a desorption property, a vapor pressure, etc.) of the precursor gas and the reaction gas used for forming these films, it is possible to obtain the same effects as described above

In the foregoing descriptions, the second heating part 271 is divided into the central portion 271a, the intermediate portion 271b and the peripheral portion 271c so as to heat three zones. However, the present disclosure is not limited thereto. The second heating part 271 may be configured to correspond to, for example, two zones or four or more zones as long as the temperature of the zone facing the second exhaust port 240 can be set higher than the temperature of other zones.

According to the present disclosure in some embodiments, it is possible to improve at least the processing uniformity of a substrate.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a substrate support part provided with a first heating part configured to heat a substrate;
a gas supply part installed above the substrate support part and configured to supply a process gas to the substrate;
a first exhaust port configured to exhaust an atmosphere of a process space existing above the substrate support part;
a gas distribution part installed to face the substrate support part;
a lid part provided with a second exhaust port configured to exhaust a buffer space existing between the gas supply part and the gas distribution part;
a rectifying part installed within the buffer space and provided with a second heating part at least partially facing the second exhaust port, the rectifying part configured to rectify the process gas; and
a control part configured to control the second heating part.

2. The apparatus of claim 1, wherein the second heating part is divided into a plurality of zones, and
the control part is configured to control the second heating part such that a temperature of a zone facing the second exhaust port becomes higher than a temperature of other zones.

3. The apparatus of claim 1, wherein the control part is configured to control the second heating part such that a temperature of a buffer-space-side surface of the gas distribution part and a temperature of a process-space-side surface of the gas distribution part become equal to each other.

4. The apparatus of claim 2, wherein the control part is configured to control the second heating part so that a temperature of a buffer-space-side surface of the gas distribution part and a temperature of a process-space-side surface of the gas distribution part become equal to each other.

5. The apparatus of claim 1, wherein a third heating part is installed in the lid part, and the control part is configured to control the third heating part such that the lid part has a temperature at which the process gas is not adsorbed onto the lid part.

6. The apparatus of claim 4, wherein a third heating part is installed in the lid part, and the control part is configured to control the third heating part such that the lid part has a temperature at which the process gas is not adsorbed onto the lid part.

7. The apparatus of claim 1, wherein a heat insulation part is installed between an outer periphery portion of the lid part and an outer periphery portion of the gas distribution part.

8. The apparatus of claim 4, wherein a heat insulation part is installed between an outer periphery portion of the lid part and an outer periphery portion of the gas distribution part.

9. The apparatus of claim 5, wherein a heat insulation part is installed between an outer periphery portion of the lid part and an outer periphery portion of the gas distribution part.

10. The apparatus of claim 1, wherein an outer peripheral edge of the second heating part is positioned more outward than an outer peripheral edge of the substrate.

11. The apparatus of claim 7, wherein an outer peripheral edge of the second heating part is positioned more outward than an outer peripheral edge of the substrate.

12. The apparatus of claim 8, wherein an outer peripheral edge of the second heating part is positioned more outward than an outer peripheral edge of the substrate.
